(19) United States
(12) Patent Application Publication
(10) Pub. No.: US 2015/0270419 A1
(43) Pub. Date: Sep. 24, 2015

(54) PHOTOELECTRIC CONVERSION ELEMENT AND MANUFACTURING METHOD OF PHOTOELECTRIC CONVERSION ELEMENT

(71) Applicant: Mitsubishi Electric Corporation, Chiyoda-ku (JP)

(72) Inventors: Yohei YUDA, Tokyo (JP); Takayuki MORIOKA, Tokyo (JP); Tsutomu MATSUURA, Tokyo (JP); Tatsuro WATAHIKI, Tokyo (JP)

(73) Assignee: Mitsubishi Electric Corporation, Chiyoda-ku (JP)

(21) Appl. No.: 14/657,504

(22) Filed: Mar. 13, 2015

(30) Foreign Application Priority Data
Mar. 24, 2014 (JP) 2014-060050
Dec. 2, 2014 (JP) 2014-243877

(51) Int. Cl. H01L 31/0224; H01L 31/18

(52) U.S. Cl. CPC H01L 31/022433; H01L 31/022466; H01L 31/1884; H01L 31/1872

(57) ABSTRACT

A photoelectric conversion element includes: a photoelectric conversion layer; and first and second electrodes formed on surfaces of the photoelectric conversion layer, wherein at least one of the first and second electrodes includes a translucent conductive base layer made of a translucent conductive material, and a translucent conductive mesh layer selectively buried in the translucent conductive base layer, having electrical resistivity lower than electrical resistivity of the translucent conductive base layer, and formed in a translucent conductive film pattern.

### BACKGROUND OF THE INVENTION

1. Field of the Invention

The present invention relates to a photoelectric conversion element and a manufacturing method of a photoelectric conversion element.

2. Description of the Related Art

Conventionally, devices having translucent conductive films have been actively studied in various types of solar cells, including thin-film silicon solar cells, heterojunction silicon solar cells, and organic solar cells, organic electroluminescence (organic EL) devices, touch panels, mobile phones, electronic paper, and the like. In photoelectric conversion devices, translucent electrodes ace one of the important elements. High light permeability and conductivity are required for translucent electrodes. Mainly, the light permeability affects the short-circuit current density and the conductivity affects the fill factor. Particularly, when only a translucent electrode is used as an electrode on the light-receiving surface side, the electric current generated in the photoelectric conversion layer has a transverse current path, and thus it is important to improve the conductivity.

Furthermore, a translucent electrode substrate having a translucent conductive film formed on a substrate such as a glass substrate has been generally used as an electrode in electronic devices such as solar cells and organic EL devices. However, with a translucent electrode substrate in which a normal metal oxide such as tin-doped indium oxide is used as the translucent conductive film, the translucent conductive film has high electrical resistivity. It is assumed here that the electrical resistivity means volume resistivity. With respect to this issue, a translucent electrode substrate in which a metal material layer having extremely low electrical resistivity compared with that of the translucent conductive film is used as a supplemental electrode has been studied.

For example, in Japanese Patent Application Laid-open No. H10-241464, a substrate with a translucent conductive film in which a translucent oxide layer, a metal layer, a translucent oxide layer are laminated on a substrate in this order has been disclosed.

Further, in Japanese Patent Application Laid-open No. 2012-142500, there is a disclosure of a translucent electrode substrate in which, in order to improve translucency, conductivity, and durability of the translucent electrode substrate, a translucent conductive layer having a conductive metal mesh layer buried therein is laminated on one of the surfaces of a translucent base material as an electrode of an electronic device.

However, according to the technique disclosed in Japanese Patent Application Laid-open No. H10-241464, the substrate has low light permeability and is not practical as a translucent electrode substrate of a thin-film device. Further, because the metal layer is laminated on the entire surface of the translucent oxide layer, the durability of the thin-film device using the substrate with the translucent conductive film becomes a problem in some cases due to the deterioration of the metal layer.

Further, due to a decrease of light permeability due to the use of metal in the mesh layer, the amount of light entering the photoelectric conversion layer decreases, and a decrease in short-circuit current density J_{sc} becomes a concern. The method of forming the metal mesh layer requires patterning using photolithography, thereby deteriorating the workability.

### SUMMARY OF THE INVENTION

It is an object of the present invention to at least partially solve the problems in the conventional technology.

According to an aspect of the present invention, a photoelectric conversion element includes: a photoelectric conversion layer; and first and second electrodes formed on surfaces of the photoelectric conversion layer, wherein at least one of the first and second electrodes includes a translucent conductive base layer made of a translucent conductive material, and a translucent conductive mesh layer selectively buried in the translucent conductive base layer, having electrical resistivity lower than electrical resistivity of the translucent conductive base layer, and formed in a translucent conductive film pattern.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIGS. 1A to 1C are diagrams showing a photoelectric conversion element using a translucent conductive film according to a first embodiment, in which FIG. 1A is a plan view, FIG. 1B is a cross-sectional view taken along line A-A in FIG. 1A, and FIG. 1C is a diagram corresponding to a cross-sectional view taken along line B-B in FIG. 1B;

FIGS. 2A to 2D are process sectional views showing manufacturing processes of the photoelectric conversion element according to the first embodiment;

FIG. 3 is a diagram showing a modification of the translucent conductive film according to the first embodiment;

FIGS. 4A to 4C are diagrams showing a photoelectric conversion element using a translucent conductive film according to a second embodiment, in which FIG. 4A is a plan view, FIG. 4B is a cross-sectional view taken along line A-A in FIG. 4A, and FIG. 4C is a diagram corresponding to a cross-sectional view taken along line B-B in FIG. 4B;

FIGS. 5A to 5C are diagrams showing a photoelectric conversion element using a translucent conductive film according to third to fifth embodiments, corresponding to a cross-sectional view taken along line A-A in FIG. 4A;

FIG. 6 is a characteristic diagram showing a comparison of the reflectance of silver that is a conductive metal mesh layer in a comparative example and a translucent conductive material according to the present embodiment;

FIG. 7 is a characteristic diagram showing a relation between the electrical resistivity of a translucent conductive layer used in the present embodiment and an aperture ratio and the conversion efficiency of a photoelectric conversion element; and

FIG. 8A is a table showing a comparison of the electrical resistivity of a light-receiving-surface-side translucent conductive film, the carrier concentration, a theoretical value of carrier mobility, and solar cell characteristics, and FIG. 8B is a table showing the result of measurement of characteristics of a heterojunction silicon solar cell in Examples and comparative examples.

### DETAILED DESCRIPTION OF THE PREFERRED EMBODIMENTS

Exemplary embodiments of a manufacturing method of a photoelectric conversion element according to the present invention will be explained in detail below with reference to the accompanying drawings. The present invention is not limited to the embodiments and may be appropriately modified without departing from the scope of the invention. In the drawings described below, for ease of understanding, scales of respective layers or respective members may be shown differently from what they actually are in reality. This holds true for the relations between the drawings too. Hatching is applied even to plan views in some cases in order to facilitate visualization of the drawings.

### First Embodiment

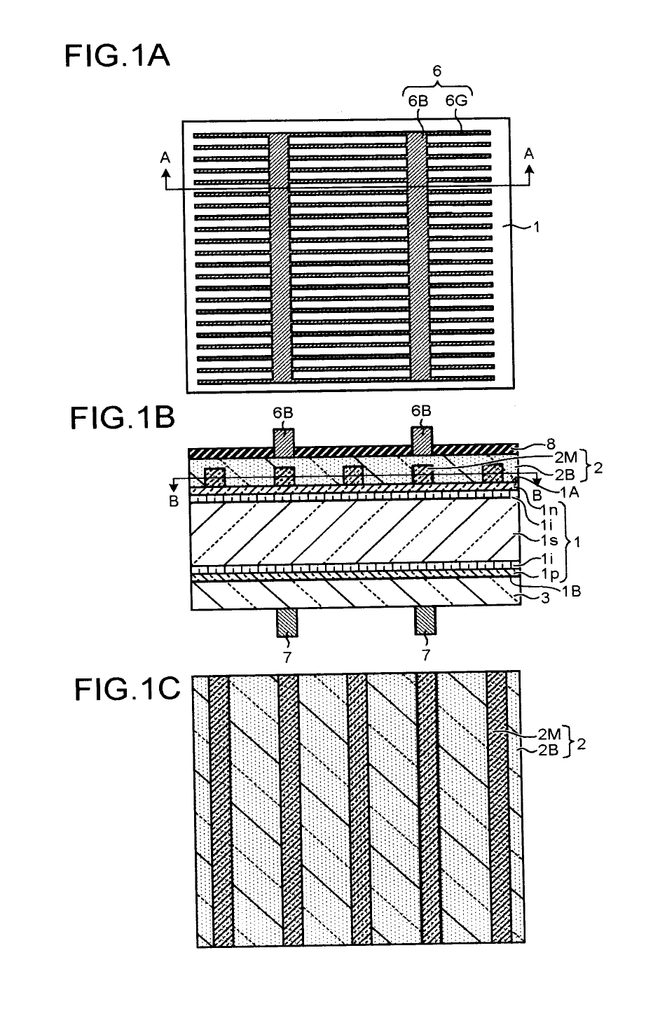

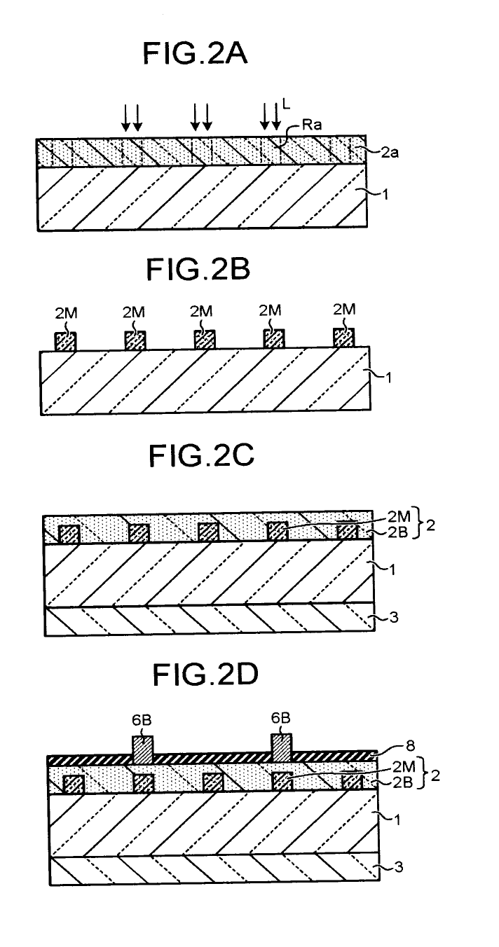

FIGS. 1A to 1C are diagrams showing a photoelectric conversion element using a translucent conductive film according to a first embodiment. FIG. 1A is a plan view, FIG. 1B is a cross-sectional view taken along line A-A in FIG. 1A, and FIG. 1C is a diagram corresponding to the cross-sectional view taken along line B-B in FIG. 1B. FIGS. 2A to 2D are process sectional views showing manufacturing processes of the photoelectric conversion element. A light-receiving-surface-side translucent conductive film 2 used for the photoelectric conversion element of the first embodiment is configured from a translucent conductive base layer 2B, which is formed on a first principal surface 1A of a photoelectric conversion layer 1 and in which a translucent conductive mesh layer 2M having low resistance is buried.

The light-receiving-surface-side translucent conductive film 2 having excellent light transmittance and electrical conductivity is obtained by forming a first translucent conductive film having relatively high electrical conductivity on the photoelectric conversion layer 1, performing a patterning process on the first translucent conductive film to form the translucent conductive mesh layer 2M in a striped pattern, and burying the translucent conductive mesh layer 2M in the translucent conductive base layer 2B made of a second translucent conductive material.

A first collective electrode 6 including a metal grid electrode 6G and a metal bus electrode 6B is formed on the light-receiving-surface-side translucent conductive film 2.

A rear-surface-side translucent conductive film 3 formed of the same material as the translucent conductive base layer 2B made of the second translucent conductive material is also formed on a second principal surface 1B, that is, on the rear surface side of the photoelectric conversion layer 1. A second collective electrode 7 formed of a metal electrode is formed on the rear-surface-side translucent conductive film 3.

The first translucent conductive material forming the translucent conductive mesh layer 2M is not particularly limited. However, the first translucent conductive material needs to be a material that is amorphous when it is formed and is solid-phase crystallized by being irradiated with laser beams. For example, an indium oxide film is used therefor. Indium oxide is one of the translucent conductive oxides generally used as a translucent electrode material. The first translucent conductive material contains indium oxide as a main component of the composition and hydrogen atom (H) as an additive with respect to indium oxide, thereby having amorphous characteristics when it is formed. The electrical resistivity of the first translucent conductive material can be controlled by containing at least one type of impurity element, such as tin (Sn), zirconium (Zr), titanium (Ti), niobium (Nb), cerium (Ce), gadolinium (Gd), and molybdenum (Mo).

The material of the translucent conductive base layer 2B made of the second translucent conductive material needs to be a material having higher light transmittance (translucency) than the translucent conductive mesh layer 2M in a crystallized state. As the material thereof, inorganic-material thin films of conductive metal oxides, for example, oxides of indium, tin, zinc, and gallium, and complex oxide of these elements, can be mentioned. More specifically, there can be mentioned hydrogenated indium oxide (IOH), tin-doped indium oxide (ITO), iridium oxide (IrO₂), indium oxide (In₂O₃), tin oxide (SnO₂), fluorine-doped tin oxide (FTO), indium zinc oxide (IZO), zinc oxide (ZnO), gallium-doped zinc oxide (GZO), aluminum-doped zinc oxide (AZO), molybdenum oxide (MoO₃), titanium oxide (TiO₂), oxide containing indium, gallium, and zinc (IGZO), and the like.

When the thickness of the translucent conductive film is increased, a decrease of electrical resistivity can be expected; however, the light transmittance thereof decreases. In contrast, when the thickness of the translucent conductive film is reduced, improvement of light transmittance can be expected; however, the electrical resistivity increases. Therefore, when the translucent conductive film is used in photoelectric conversion elements, an appropriate film thickness needs to be selected for each photoelectric conversion element. The thickness of the light-receiving-surface-side translucent conductive film 2 shown in FIG. 1B is preferably from 20 nanometers to 1000 nanometers, more preferably from 30 nanometers to 500 nanometers, and most preferably from 40 nanometers to 200 nanometers. It is preferable that the thickness of the translucent conductive mesh layer 2M, which is formed on the first principal surface 1A of the photoelectric conversion layer 1 and is made of the first translucent conductive material, is generally from 10 nanometers to 500 nanometers, and is desirably equal to or less than half the thickness of the translucent conductive base layer 2B made of the second translucent conductive material, from the viewpoint of the translucency and conductivity. When the thickness of the translucent conductive mesh layer 2M is equal to or less than half the thickness of the translucent conductive base layer 2B, both improvement of light transmittance and a decrease of electrical resistivity of the light-receiving-surface-side translucent conductive film 2 can be achieved. A method of forming the translucent conductive mesh layer 2M and the translucent conductive base layer 2B is not particularly limited, and known methods can be used. For example, various film forming methods, such as a sputtering method, an electron beam deposition method, an atomic layer deposition method, a chemical vapor deposition (CVD) method, a metal organic chemical vapor deposition (MOCVD) method, a sol-gel method, a printing method, a spray method, a reactive plasma deposition (RPD) method, and an ion plating method, can be used for forming the film, and the method is appropriately selected according to the material of the translucent conductive film.

In the light-receiving-surface-side translucent conductive film 2 according to the present embodiment, the translucent conductive base layer 2B has a structure such that it is laminated on one of the surfaces of the photoelectric conversion layer 1 in a form in which the translucent conductive mesh layer 2M having relatively high conductivity is buried therein. It is preferable that the translucent conductive mesh layer 2M is buried in the translucent conductive base layer 2B at a position closer to the surface on the side of the photoelectric conversion layer 1. That is, when it is assumed that the entire thickness of the translucent conductive base layer 2B is 100%, it is preferable that the translucent conductive mesh layer 2M is buried at a position within a distance range from 1% to 50%, from the side of the photoelectric conversion layer 1, of the entire thickness of the translucent conductive base layer 2B. When the position where the translucent conductive mesh layer 2M is buried is within this range, improvement of both electrical conductivity and light transmittance can be achieved and thus improvement of conversion efficiency of the photoelectric conversion element can be expected.

This is because the translucent conductive mesh layer 2M having excellent conductivity is buried in the translucent conductive base layer 2B on the side closer to the photoelectric conversion layer 1, thereby reducing the electrical resistivity of the light-receiving-surface-side translucent conductive film 2 and thus enabling the conductivity to be improved.

For example, when the translucent conductive mesh layer 2M is used in a heterojunction silicon solar cell, as shown in FIGS. 1A and 1C, it is preferable to form the translucent conductive mesh layer 2M as stripes in a direction orthogonal to the metal grid electrode 6G on the surface, that is, parallel to the metal bus electrode 6B. The reason why the translucent conductive mesh layer 2M is formed such that it has a striped pattern in the present embodiment is because large improvement of conductivity cannot be expected by forming the translucent conductive mesh layer 2M vertically and horizontally as a mesh and there is a concern about absorption losses due to the layer being formed as a mesh.

That is, when the translucent conductive mesh layer 2M is used in a heterojunction silicon solar cell, the translucent conductive mesh layer 2M is buried in the translucent conductive base layer 2B as stripes, not as a mesh, in the direction orthogonal to the metal grid electrode 6G, thereby reducing the electrical resistivity of the light-receiving-surface-side translucent conductive film 2 and thus further improving the conversion efficiency of the solar cell. When the translucent conductive mesh layer as stripes is formed in parallel with the metal grid electrode 6G, it is desired to form a pattern configuration such that a pattern of the translucent conductive mesh layer 2M is present at least between the metal grid electrodes 6G. Accordingly, the light-receiving-surface-side translucent conductive film 2 in which the direction of conductivity in the substrate surface is more uniform can be obtained.

Subsequently, an explanation will be given of a method of burying the translucent conductive mesh layer 2M in the light-receiving-surface-side translucent conductive film 2 provided in the photoelectric conversion element. The method of burying the translucent conductive mesh layer 2M is net particularly limited, and known methods can be appropriately selected according to the material of the translucent conductive mesh layer 2M and the shape of a mesh. For example, by performing various known mechanical processes or chemical processes, such as a method of forming a mesh pattern by etching a film made of the first translucent conductive material by using a patterning processing method using photolithography, the film is processed in a translucent conductive mesh shape, thereby forming the translucent conductive mesh layer 2M. The patterning processing method using photolithography is a method of etching a film made of the first translucent conductive material by using a photoresist pattern formed by using a photolithography method so as to form a mesh pattern.

An example of a method of forming the translucent conductive mesh layer 2M according to the present invention is explained below. First, as shown in FIG. 2A, an indium oxide layer having relatively low electrical resistivity is formed by a sputtering method on one of the surfaces of the photoelectric conversion layer 1 so as to form a film 2a, which is an amorphous thin film and is made of the first translucent conductive material, and an irradiation area Ra is solid-phase crystallized by irradiating the film 2a made of the first translucent conductive material with laser beams L.

Generally, it is known that a crystallized translucent conductive film has excellent chemical resistance and an amorphous translucent conductive film has poor chemical resistance. For example, indium oxide, which is a general translucent conductive material, is explained. As an indium oxide film, an amorphous film that is formed on a glass substrate, a plastic substrate, or the like is mainly used because of its ease of processing, that is, ease of etching. Meanwhile, a crystalline indium oxide film has advantages such as low electrical resistivity, excellent electric property, and high durability. As etchant for the indium oxide film, hydrochloric acid, sulfuric acid, nitric acid, hydroiodic acid, oxalic acid solution or the like is used. For example, an oxalic acid solution is relatively cheap and has excellent chemical stability. Further, amorphous indium oxide has a characteristic of being soluble and crystalline indium oxide has a characteristic of being insoluble.

By utilizing the chemicals described above, as shown in FIG. 2B, wet etching is performed by utilizing properties such that the crystallized film of the first translucent conductive material has excellent chemical resistance and the amorphous film 2a of the first translucent conductive material has poor chemical resistance, thereby forming the translucent conductive mesh layer 2M on the photoelectric conversion element.

Subsequently, as shown in FIG. 2C, an indium oxide layer is formed by a sputtering method so as to cover the translucent conductive mesh layer 2M with the translucent conductive base layer 2B made of the second translucent conductive material. It is assumed here that the indium oxide layer has higher translucency than the film constituting the translucent conductive mesh layer 2M. According to this method, the light-receiving-surface-side translucent conductive film 2 having the translucent conductive mesh layer 2M buried therein is laminated on one of the surfaces of the photoelectric conversion layer 1. Impurities used here is hydrogen (H) or the like. By controlling the concentration of hydrogen to be added to indium oxide, the conductivity and the translucency can be controlled. The same applies to impurities, such as tin (Sn), that are generally added to indium oxide. In this manner, the photoelectric conversion element according to the present embodiment shown in FIGS. 1A to 1C can be manufactured efficiently. Various types of patterns in addition to a stripe can be easily formed for the translucent conductive mesh layer 2M.

Further, as shown in FIG. 2D, the first collective electrode 6 including the metal bus electrode 6B (and the metal grid electrode 6G) is formed. On the side of the second principal surface 1B, which is a rear surface, the rear-surface-side translucent conductive film 3 and the second collective electrode 7 are formed, thereby forming the photoelectric conversion element.

In this manner, by forming the translucent conductive base layer 2B made of the second translucent conductive material on the translucent conductive mesh layer 2M according to the method described above, the photoelectric conversion element in which the translucent conductive mesh layer 2M is buried inside the translucent conductive base layer 2B can be obtained.

According to the above configuration, because the translucent conductive mesh layer 2M is buried in the translucent conductive base layer 2B made of the second translucent conductive material, the light transmittance of the light-receiving-surface-side translucent conductive film 2 is improved as compared to a photoelectric conversion element having a conventional structure that is obtained by processing conductive metal as a mesh.

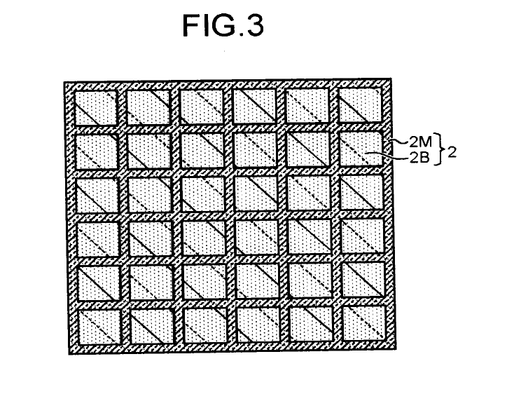

As a modification thereof, the pattern of the translucent conductive mesh layer 2M can be formed as a mesh as shown in FIG. 3. According to this configuration, although the light transmittance slightly decreases, the conductivity is improved.

Further, while the sputtering method is used for forming the translucent conductive mesh layer 2M and the translucent conductive base layer 2B, the film-forming method is not limited to the sputtering method, and other film-forming methods such as a CVD method and an RPD method can be used.

### Second Embodiment

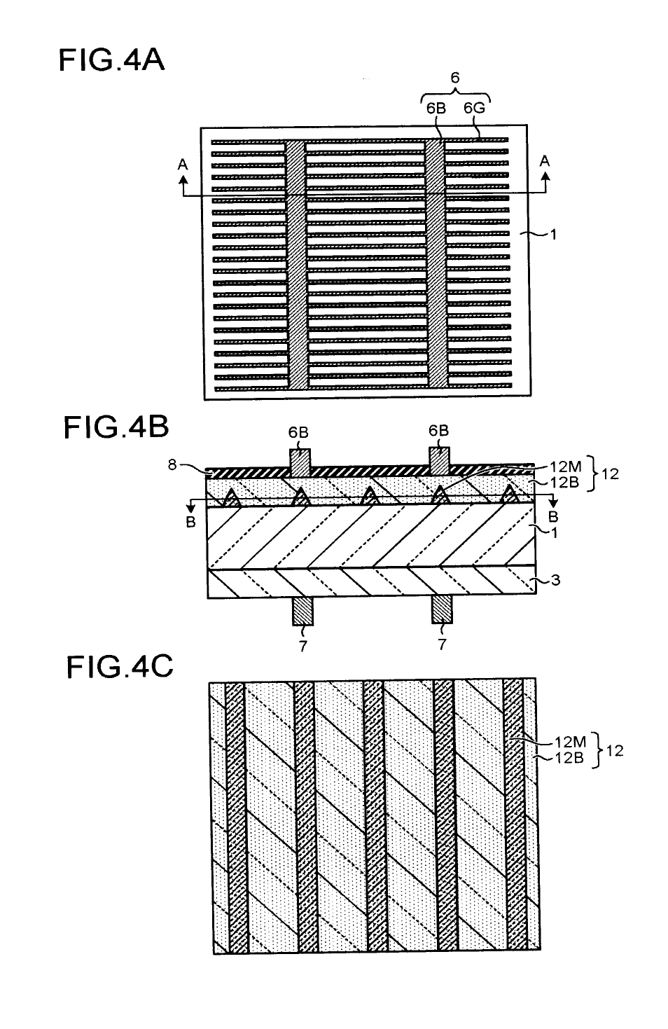

FIGS. 4A to 4C are diagrams showing a photoelectric conversion element using a translucent conductive film according to a second embodiment. FIG. 4A is a plan view, FIG. 4B is a cross-sectional view taken along line A-A in FIG. 4A, and FIG. 4C is a diagram corresponding to the cross-sectional view taken along line B-B in FIG. 4B. The photoelectric conversion element according to the second embodiment is characterized such that a light-receiving-surface-side translucent conductive film 12 includes a translucent conductive mesh layer 12M having a tapered cross-section and a translucent conductive base layer 12B covering the translucent conductive mesh layer 12M. The tapered cross-section is formed by setting the pattern width to be smaller on the side of the first collective electrode 6, that is, on the side of the light source provided on the upper side than that on the side of the photoelectric conversion layer 1 provided on the lower side. Other characteristics of the second embodiment are identical to those described in the first embodiment.

The translucent conductive mesh layer 2M according to the first embodiment can improve the conversion efficiency of the photoelectric conversion element because of a large decrease of reflectance, as compared to the conventional conductive metal mesh layer. However, the free carrier absorption in the near-infrared region increases because of high carrier concentration, as compared to the translucent conductive base layer 2B made of the second translucent conductive material. It is generally known that the absorption rate increases because of the free carrier absorption in the near-infrared region from around a point where the carrier concentration exceeds about 10¹⁸ cm⁻³, and thus the light transmittance decreases so as to cause optical losses. That is, when a translucent conductive oxide film TCO is used as the translucent conductive film of a photoelectric conversion element that utilizes light of a long wavelength equal to or longer than the near-infrared region, control of the carrier concentration becomes important.

According to the present embodiment, by changing the cross-sectional shape of the translucent conductive mesh layer 12M from the rectangular shape of the first embodiment to the tapered shape as shown in FIG. 4B, incident light rays can be scattered and caused to enter the photoelectric conversion layer 1 more efficiently, thereby enabling the photoelectric losses to be reduced. Formation of the translucent conductive mesh layer 12M in a tapered shape is realized by setting the focal point of the laser beam to the upper side of the film made of the first translucent conductive material formed of an amorphous material and reducing the spot diameter. That is, laser irradiation is performed such that a substantially conical region becomes a solid-phase crystallized portion. An amorphous region excluding the crystallized irradiated region is removed by etching with an oxalic acid solution. A mesh pattern having a conical shape in cross section can be obtained in this manner.

Other portions are formed in a similar manner to those in the first embodiment, thereby forming the photoelectric conversion element having the translucent conductive film in which the translucent conductive mesh layer is buried as shown in FIGS. 4A and 4B.

### Third Embodiment

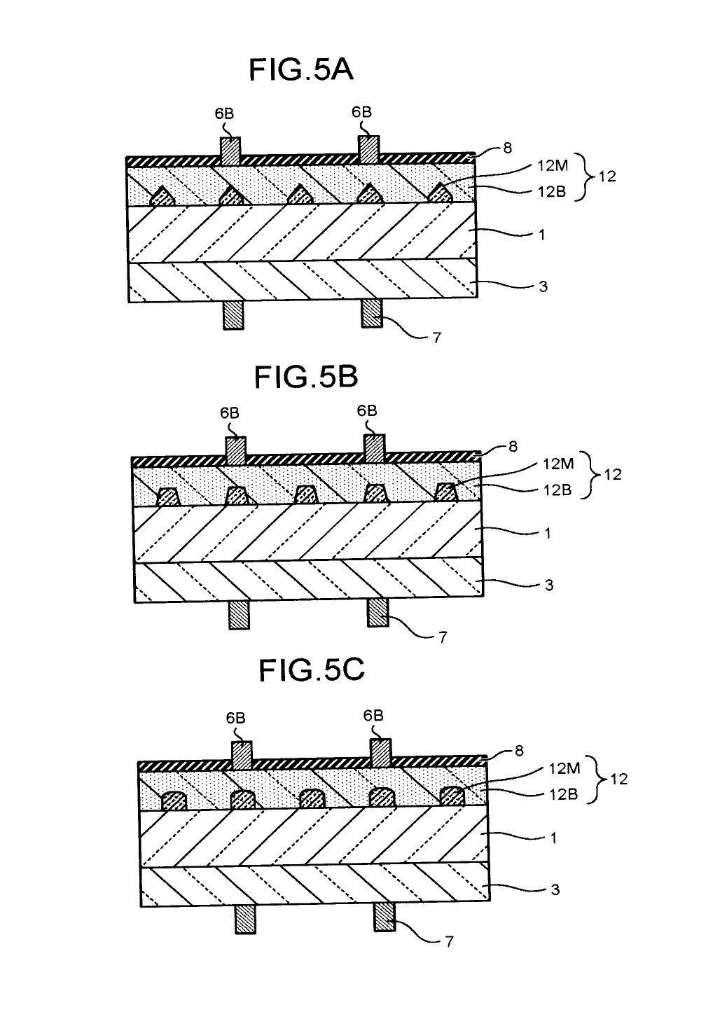

FIG. 5A is a cross-sectional view showing a photoelectric conversion element using a translucent conductive film according to a third embodiment. FIG. 5A is a diagram corresponding to the cross-sectional view taken along line A-A in FIG. 4A. The photoelectric conversion element according to the third embodiment is characterized such that the light-receiving-surface-side translucent conductive film 12 includes the translucent conductive mesh layer 12M having a tapered cross-section in which an upper part of a rectangular pattern has a triangular shape in cross section, and the translucent conductive base layer 12B that covers the translucent conductive mesh layer 12M. The tapered cross-section is formed by setting the pattern width to be smaller on the side of the first collective electrode 6, that is, on the side of the light source provided on the upper side than that on the side of the photoelectric conversion layer 1 provided on the lower side. Other characteristics of the third embodiment are identical to those described in the first and second embodiments.

According to the present embodiment, as compared to the rectangular shape of the first embodiment, the amount of light entering the photoelectric conversion layer 1 can be increased. Further, as compared to the triangular shape in cross section of the second embodiment, the electrical resistivity can be decreased.

When the translucent conductive mesh layer 12M is formed, laser irradiation is separately performed twice so as to facilitate the formation. Alternatively, laser irradiation is performed by using the same mask and the irradiation angle of the laser is changed in the middle of patterning irradiation, whereby the cross-sectional shape of the present embodiment can be obtained.

The photoelectric conversion efficiency can be increased by forming the translucent conductive mesh layer 12M such that it has a multi-layer structure in which, for example, a rectangular pattern portion having a rectangular shape in cross section and a triangular pattern portion having a triangular shape in cross section are made of materials having different translucency or refractive index.

### Fourth Embodiment

FIG. 5B is a cross-sectional view showing a photoelectric conversion element using a translucent conductive film according to a fourth embodiment. FIG. 5B is a diagram corresponding to the cross-sectional view taken along line A-A in FIG. 4A. The photoelectric conversion element according to the fourth embodiment is characterized such that the light-receiving-surface-side translucent conductive film 12 includes the translucent conductive mesh layer 12M having a tapered cross-section in the shape of a trapezoid, and the translucent conductive base layer 12B that covers the translucent conductive mesh layer 12M. The tapered cross-section is formed by setting the pattern width to be smaller on the side of the first collective electrode 6, that is, on the side of the light source provided on the upper side than that on the side of the photoelectric conversion layer 1 provided on the lower side. Other characteristics of the fourth embodiment are identical to those described in the first and second embodiments.

When the translucent conductive mesh layer 12M is formed, a triangular pattern having a triangular shape in cross section is formed and the top surface is irradiated with high-energy laser so as to cause a deformation of the pattern, thereby obtaining the translucent conductive mesh layer 12M having a tapered cross-section in the shape of a trapezoid.

The photoelectric conversion efficiency can be increased by forming the translucent conductive mesh layer 12M such that it has a multi-layer structure in which, for example, a rectangular pattern portion having a rectangular shape in cross section and a triangular pattern portion having a triangular shape in cross section are made of materials having different translucency or refractive index.

According to the present embodiment, as compared to the rectangular shape of the first embodiment, the pattern shape is stable and the amount of light entering the photoelectric conversion layer 1 can be increased.

### Fifth Embodiment

FIG. 5C is a cross-sectional view showing a photoelectric conversion element using a translucent conductive film according to a fifth embodiment. FIG. 5C is a diagram corresponding to the cross-sectional view taken along line A-A in FIG. 4A. The photoelectric conversion element according to the fifth embodiment is characterized such that the light-receiving-surface-side translucent conductive film 12 includes the translucent conductive mesh layer 12M having a tapered cross-section in the shape of a half moon, and the translucent conductive base layer 12B that covers the translucent conductive mesh layer 12M. The tapered cross-section in the shape of a half moon is formed by setting the pattern width to be smaller on the side of the first collective electrode 6, that is, on the side of the light source provided on the upper side than that on the side of the photoelectric conversion layer 1 provided on the lower side. Other characteristics of the fifth embodiment are identical to those described in the first and second embodiments.

According to the present embodiment, as compared to the rectangular shape of the first embodiment, the amount of light entering the photoelectric conversion layer 1 can be increased. Further, by suppressing the area of a portion of the photoelectric conversion layer 1 shielded by the translucent conductive mesh layer 12M to the minimum while increasing the sectional area of the translucent conductive mesh layer 12M having relatively low electrical resistivity as large as possible so as to achieve low resistance, the photoelectric conversion efficiency can be increased.

The translucent conductive mesh layer 12M can be easily formed by using a printing method. The translucent conductive mesh layer 12M having a tapered cross-section in the shape of a half moon can be obtained by forming a rectangular pattern in cross section by using the printing method and firing the printed pattern after once melting and rounding the printed pattern by surface tension.

The method of burying the translucent conductive mesh layer 2M or 12M in the light-receiving-surface-side translucent conductive film 2 or 12 described in the first to fifth embodiments is not particularly limited, and known methods can be appropriately selected according to the material of the translucent conductive mesh layer 2M or 12M and the shape of the mesh. For example, the method of, after the amorphous translucent conductive layer is solid-phase crystallized by laser irradiation, removing the amorphous region by etching, the method of, after the amorphous translucent conductive layer formed by using a photolithography method is solid-phase crystallized by firing, removing the amorphous region by etching, and the like described above can be appropriately used. When a pattern of the translucent conductive mesh layer is formed, also in the first and second embodiments, the film composition at the time of film formation can be changed so as to have a multi-layer structure as in the third and fourth embodiments. Alternatively, also in the embodiments other than the fourth embodiment, pattern formation can be performed by a printing method by making full use of multi-layer printing, multi-step firing, or the like. Also by adjusting the laser beams or using a two-step etching, the cross-sectional shape of the translucent conductive mesh layer shown in the first to fifth embodiments can be easily controlled.

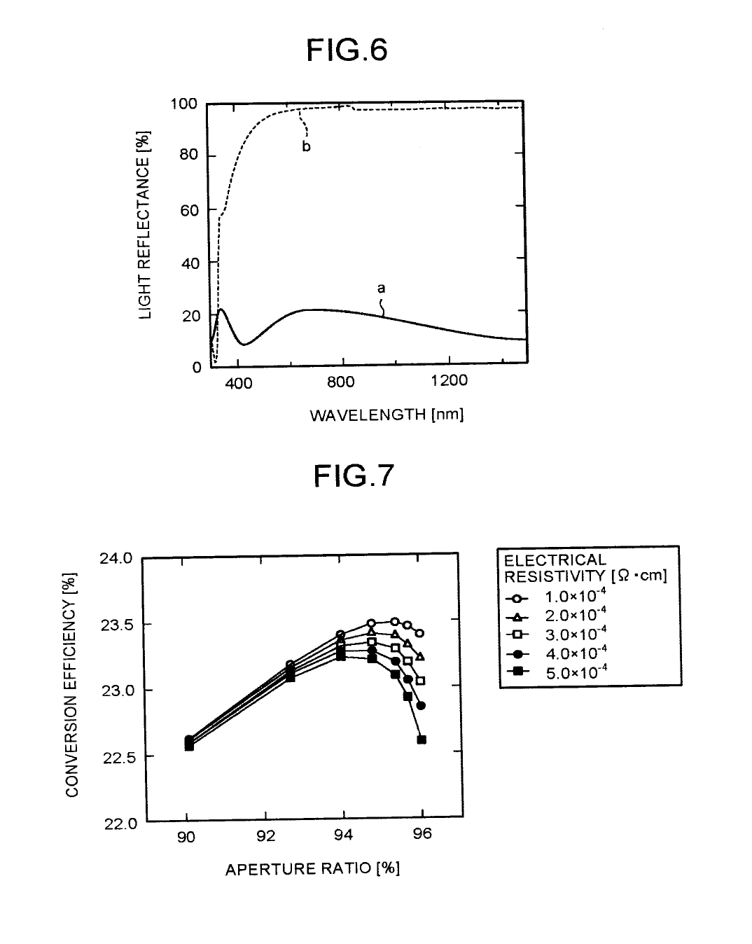

FIG. 6 is a diagram showing the result of measurement of reflectance of indium oxide that is the first translucent conductive material used for the translucent conductive mesh layer 2M and silver (Ag) that is a representative metal used in the conventional metal mesh layer. In FIG. 6, “a” denotes a curve showing light reflectance of the first translucent conductive material, and “b” denotes a curve showing light reflectance of silver. The light reflectance is plotted on the vertical axis and the wavelength is plotted on the horizontal axis. As is obvious from FIG. 6, there is a large difference in reflectance between silver that is a metal film and indium oxide that is the first translucent conductive material. By using the translucent conductive material having small reflectance for the translucent conductive mesh layer 2M, the amount of light entering the photoelectric conversion layer 1 can be increased. Therefore, the conversion efficiency of the photoelectric conversion element can be improved. In this case, the structure of the translucent conductive mesh layer 2M can be a linear pattern or a net-like pattern, and the shape thereof is not particularly limited and can be appropriately selected according to the desired conductivity, light permeability, strength, and the like.

FIG. 7 is a characteristic diagram showing, by simulation, the relation between electrical resistivity of the translucent conductive material used for the light-receiving-surface-side translucent conductive film 2 according to the embodiments of the present invention and conversion efficiency of the heterojunction silicon solar cell. In FIG. 7, the light transmittance of the translucent conductive material is not taken into consideration. It is considered here that the conversion efficiency of the photoelectric conversion element is simply improved as the electrical resistivity decreases. It is understood that when a translucent conductive film having each electrical resistivity is used for a light-receiving-surface-side electrode, an optimum opening area is present for each case. When the light transmittance of the translucent conductive film is taken into consideration in this result, as described above, a gap between the metal grid electrodes 6G on the surface can be increased due to a decrease of electrical resistivity by burying the translucent conductive mesh layer 2M having relatively low electrical resistivity in the translucent conductive base layer 2B made of the second translucent conductive material having relatively high light transmittance. Consequently, the aperture ratio is improved, thereby enabling the amount of light entering the photoelectric conversion layer 1 of the photoelectric conversion element to be increased. Accordingly, the short-circuit current density increases and the fill factor is improved due to a decrease of electrical resistivity of the light-receiving-surface-side translucent conductive film 2; therefore, the conversion efficiency of the photoelectric conversion element is improved. Further, according to the present embodiment, because the translucent conductive mesh layer 2M having translucency that is at least higher than that of the translucent conductive film in which the conventional metal mesh layer is buried in the translucent conductive base layer is used in the photoelectric conversion element, the short-circuit current density can be improved.

In the photoelectric conversion element according to the present embodiment, the collective electrode is configured from the light-receiving-surface-side translucent conductive film 12 including the translucent conductive mesh layer 12M having a tapered cross-section and patterned as a mesh and the translucent conductive base layer 12B having the translucent conductive mesh layer 12M buried therein and made of the second translucent conductive material having low electrical resistivity, and the first collective electrode 6, which is the light-receiving-surface-side metal electrode. FIGS. 4A to 4C are cross-sectional views showing an example of layers constituting the heterojunction silicon solar cell that is an example of the solar cell according to the present invention. Also in the present embodiment, components other than the light-receiving-surface-side translucent conductive film 12 have identical configurations as those of the first embodiment. That is, the light-receiving-surface-side translucent conductive film 12 used in the photoelectric conversion element according to the fourth embodiment includes the translucent conductive base layer 12B, which is formed on the first principal surface 1A of the photoelectric conversion layer 1 and in which the translucent conductive mesh layer 12M having low resistance is buried. The first collective electrode 6, which is the light-receiving-surface-side metal electrode, is formed on the light-receiving-surface-side translucent conductive film 12, and the second collective electrode 7, which is a rear-surface-side metal electrode, is formed on the rear-surface-side translucent conductive film 3. The translucent conductive mesh layer 12M is formed on the photoelectric conversion layer 1 in an amorphous state and is then solid-phase crystallized by being irradiated with laser beams.

The result of the calculation of the electrical resistivity of the light-receiving-surface-side translucent conductive film 12 having the translucent conductive mesh layer 12M buried therein is shown below. For example, when it is assumed that the electrical resistivity of the translucent conductive base layer 12B is 3.0×10⁻⁴, the electrical resistivity of the translucent conductive mesh layer 12M is 1.5×10⁻⁴, which is half the electrical resistivity of the translucent conductive base layer 12B, and the cross-sectional ratio is 3:1, the electrical resistivity of the light-receiving-surface-side translucent conductive film 12 can be estimated to be about 2.4×10⁻⁴. In this calculation, it is considered that parallel resistance perpendicular to a cross-sectional direction is generated. This calculation is derived by using the following equations (1) and (2). In Equation (1), R denotes the resistance of the light-receiving-surface-side translucent conductive film 12, ρ denotes the electrical resistivity of the light-receiving-surface-side translucent conductive film 12, l denotes the length of the light-receiving-surface-side translucent conductive film 12, w denotes the width of the light-receiving-surface-side translucent conductive film 12, and d denotes the height of the light-receiving-surface-side translucent conductive film 12. R₁ and R₂ in Equation (2) respectively express a resistance value of the translucent conductive base layer 12B and a resistance value of the translucent conductive mesh layer 12M.

$$\begin{matrix}R = ρ \frac{l}{wd} & ( 1 ) \\ \frac{l}{R} = \frac{l}{{R}_{1}} + \frac{l}{{R}_{2}} & ( 2 )\end{matrix}$$

In the present embodiment, a patterning process is performed by laser beams in order to form the translucent conductive mesh layer 12M, thereby facilitating formation of a pattern for any purpose in a more versatile manner.

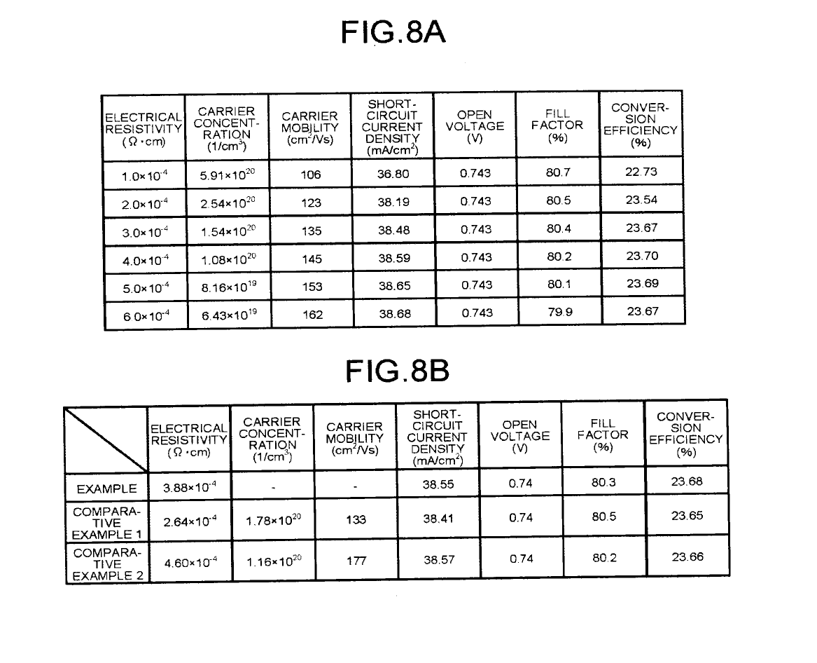

Table 1 shown in FIG. 8A shows a comparison of the electrical resistivity of the light-receiving-surface-side translucent conductive film, the carrier concentration of the translucent conductive film, a theoretical value of carrier mobility, and solar cell characteristics of a general heterojunction silicon solar cell. In the data in Table 1, the carrier concentration of the translucent conductive film and an increase of absorption rate of the light-receiving-surface-side translucent conductive film associated therewith are taken into consideration, unlike in FIG. 7. In Table 1, because the light-receiving-surface-side translucent conductive film is a single-layer film, the fill factor monotonously increases with a decrease of electrical resistivity, and as the carrier concentration of the light-receiving-surface-side translucent conductive film decreases, free-carrier absorption losses of the translucent conductive film decrease. Therefore, the short-circuit current density monotonously increases. In association with these results, the conversion efficiency of the heterojunction silicon solar cell changes, and it is understood that there is optimum electrical resistivity and carrier concentration as the light-receiving-surface-side translucent conductive film. When the electrical resistivity of the light-receiving-surface-side translucent conductive film decreases, the fill factor of the solar cell monotonously increases. However, the free carrier absorption of the light-receiving-surface-side translucent conductive film increases. Therefore, the light transmittance in a near-infrared region decreases and the short-circuit current density decreases. Accordingly, it is considered that the carrier concentration of the light-receiving-surface-side translucent conductive film needs to be optimized in order to obtain the highest conversion efficiency. Meanwhile, because of a decrease of electrical resistivity of the light-receiving-surface-side translucent conductive film, the opening area of the solar cell can be adjusted by changing the distance between the metal grid electrodes 6G on the light-receiving surface side. In order to obtain the highest conversion efficiency, the opening area needs to be optimized in addition to the optimization of carrier concentration of the light-receiving-surface-side translucent conductive film. By configuring the light-receiving-surface-side translucent conductive film 12 having the optimum electrical resistivity from the translucent conductive base layer 12B having the translucent conductive mesh layer 12M buried therein of the present embodiment, the carrier concentration can be decreased as compared to a single film of the translucent conductive base layer 12B. Consequently, an increase of short-circuit current density can be expected and excellent conductivity can be ensured.

As an Example, Table 2 in FIG. 8B shows the result of measurement of the characteristics of the heterojunction silicon solar cell in which the light-receiving-surface-side translucent conductive film 2, which is a highly permeable translucent conductive film and in which the stripe-shaped translucent conductive mesh layer 2M having a rectangular shape in cross section is buried, as in the photoelectric conversion element of the first embodiment shown in FIGS. 1A to 1C, and the first collective electrode 6 formed on the upper layer thereof are used as a collective electrode on the light-receiving surface side. For the translucent electrode on the light-receiving surface side of a heterojunction silicon solar cell of a comparative example 1, the translucent conductive film used for the stripe-shaped translucent conductive mesh layer 2M having a rectangular shape in cross section is used as a single-layer film. For the translucent electrode on the light-receiving surface side of a heterojunction silicon solar cell of a comparative example 2, a translucent conductive film having electric property equivalent to that of the translucent conductive base layer 2B is used.

The photoelectric conversion element of the present embodiment is briefly explained. In the heterojunction silicon solar cell constituting the photoelectric conversion element of the present embodiment, an n-type monocrystalline silicon substrate 1s is used as a crystalline silicon substrate. As the n-type monocrystalline silicon substrate is, a silicon substrate obtained by slicing an ingot is used. In order to prevent reflection or in order to increase the optical length in the substrate by scattering, a substrate having irregularities referred to as texture formed on the surface of the substrate is used. The schematic diagram shown in FIG. 1B shows a cross-sectional view in which the irregular shape of the substrate is omitted.

Subsequently, an i-type amorphous silicon layer 1i is formed on both sides of the n-type monocrystalline silicon substrate is by using a plasma CVD device. The i-type amorphous silicon layer 1i and an n-type amorphous silicon layer 1n are formed on the side of the first principal surface 1A, which is a light-receiving surface. The i-type amorphous silicon layer 1i and a p-type amorphous silicon layer 1p are then formed on the side of the second principal surface 1B, which is a rear surface. The light-receiving-surface-side translucent conductive film 2 having the translucent conductive mesh layer 2M buried therein is formed on the n-type amorphous silicon layer in on the side of the first principal surface 1A, and the rear-surface-side translucent conductive film 3 is formed on the rear surface side. The translucent conductive mesh layer 2M is formed in a rectangular shape in cross section and in a linear (stripe) shape. Designing is performed such that the volume of the translucent conductive mesh layer 2M becomes one third of the entire translucent conductive film. The first collective electrode 6, which is the metal electrode, and the second collective electrode 7, which is the rear-surface electrode, are formed on the both sides of the silicon substrate. The metal grid electrode 6G on the surface is formed in a direction perpendicular to a striped pattern constituting the translucent conductive mesh layer 2M. That is, the metal bus electrode 6B and the pattern of the translucent conductive mesh layer 2M are parallel to each other. Lastly, MgF₂ is formed on the surface side as an antireflection film 8.

The electrical resistivities of the rectangular stripe-shaped translucent conductive mesh layer 2M and the light-receiving-surface-side translucent conductive film 2 used as the Example are 2.64×10⁻⁴ Ω·cm and 4.60×10⁻⁴ Ω·cm, respectively, and the percentage of the rectangular stripe-shaped translucent conductive mesh layer 2M in the cross-sectional area of the entire translucent conductive film accounts for 25%. That is, it is estimated that the electrical resistivity of the light-receiving-surface-side translucent conductive film 2 having the rectangular stripe-shaped translucent conductive mesh layer 2M buried therein, which is manufactured as the Example, is 3.88×10⁻⁴ Ω·cm. Further, the carrier concentration and the carrier mobility of the light-receiving-surface-side translucent conductive film 2 used as the Example are as shown in Table 2 of FIG. 8B.

The translucent conductive films used in the heterojunction silicon solar cell, which are manufactured as the comparative example 1 and the comparative example 2 shown in Table 2, are respectively single films having electrical resistivities different from each other. When comparing the comparative example 1 and the comparative example 2, it is understood that the short-circuit current density is higher in the comparative example 2 having lower carrier concentration than in the comparative example 1 because of the effect of free carrier absorption, which depends on the carrier concentration of the translucent conductive film. On the other hand, because the electrical resistivity in the comparative example 2 is higher than that in the comparative example 1, the fill factor decreases in the comparative example 2.

The rectangular stripe-shaped translucent conductive mesh layer 2M used as the Example is the translucent conductive film used in the comparative example 1 and is buried in the light-receiving-surface-side translucent conductive film 2 used in the comparative example 2. As a result, the conversion efficiency of the heterojunction silicon solar cell is improved as compared to that of the comparative example 1 and the comparative example 2. From this result, the effectiveness has been confirmed of using the translucent conductive film according to the Example in which the translucent conductive film having relatively high carrier concentration is buried in the translucent conductive film having relatively low carrier concentration and high carrier mobility for the heterojunction silicon solar cell.

In the embodiments described above, when the light-receiving-surface-side translucent conductive film 2 is formed, the translucent conductive mesh layer 2M becomes a solid-phase crystallized portion by laser irradiation, and a region that has not been crystallized is immersed in an oxalic acid solution and removed, thereby forming the translucent conductive base layer 2B again. However, the translucent conductive base layer 2B can be formed and selectively solid-phase crystallized by laser irradiation so as to obtain a mesh pattern, and a portion that has not been crystallized can be directly used as the translucent conductive base layer without being removed. By this method, it is possible to obtain a film that can be easily manufactured and has excellent adhesion between the translucent conductive mesh layer and the translucent conductive base layer and has high reliability.

The pattern shape of the translucent conductive mesh layer 2M is not limited to a stripe shape or a mesh shape, and can be appropriately changed to a dotted shape, a shape of concentric circles, or the like. However, by using a continuous pattern, the conductivity in an extending direction thereof can be increased and thus the continuous pattern is more desirable.

The translucent conductive materials respectively constituting the translucent conductive mesh layer 2M and the translucent conductive base layer 2B can be materials having the same composition and different crystallinities, materials having different impurity concentrations, or materials having different compositions.

The translucent conductive mesh layer 2M is formed such that it is in contact with the surface of the photoelectric conversion layer. However, crystallization by laser irradiation may not completely reach the surface of the photoelectric conversion layer and the translucent conductive base layer 2B may be left between the surface of the photoelectric conversion layer and the translucent conductive mesh layer 2M.

The light-receiving-surface-side translucent conductive film 2 having the translucent conductive mesh layer 2M buried therein according to the embodiments described above has high light permeability and low electrical resistivity, and thus has a good balance between translucency and conductivity. The light-receiving-surface-side translucent conductive film 2 having the translucent conductive mesh layer 2M buried therein according to the above embodiments is applicable to solar cells such as a heterojunction silicon solar cell and an organic thin-film solar cell, and electronic devices such as transistors, memories, organic devices such as an organic EL, liquid-crystal displays, electronic paper, thin-film transistors, electrochromic devices, electrochemical luminescence devices, touch panels, displays, thermoelectric conversion devices, piezoelectric transducers, and electric storage devices.

According to the present invention, because the mesh layer buried in the translucent conductive film is not metal but a translucent conductive material, it is possible to obtain a translucent conductive film that can expect further improvement of short-circuit current and has high light transmittance and high conductivity. By using such a translucent conductive film, an effect is obtained where the photoelectric conversion efficiency of the photoelectric conversion element can be improved.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A photoelectric conversion element comprising:
a photoelectric conversion layer; and
first and second electrodes formed on surfaces of the photoelectric conversion layer, wherein
at least one of the first and second electrodes includes
a translucent conductive base layer made of a translucent conductive material, and
a translucent conductive mesh layer selectively buried in the translucent conductive base layer, having electrical resistivity lower than electrical resistivity of the translucent conductive base layer, and formed in a translucent conductive film pattern.

2. The photoelectric conversion element according to claim 1, wherein the translucent conductive mesh layer has a translucent conductive film pattern that is selectively formed such that the translucent conductive film pattern is in contact with a surface of the photoelectric conversion layer.

3. The photoelectric conversion element according to claim 1, wherein the translucent conductive mesh layer is an inorganic-material thin film.

4. The photoelectric conversion element according to claim 3, wherein the translucent conductive mesh layer is obtained by crystallizing an amorphous material.

5. The photoelectric conversion element according to claim 3, wherein
the translucent conductive base layer and the translucent conductive mesh layer are made of a same material, and
the translucent conductive mesh layer contains a dopant in higher concentration than in the translucent conductive base layer.

6. The photoelectric conversion element according to claim 1, further comprising a metal grid electrode on the translucent conductive film, wherein
the translucent conductive mesh layer has a striped pattern formed in a direction orthogonal to the metal grid electrode.

7. The photoelectric conversion element according to claim 1, further comprising a metal grid electrode on the translucent conductive film, wherein
the translucent conductive mesh layer has a pattern formed vertically and horizontally in a mesh.

8. The photoelectric conversion element according to claim 1, wherein the translucent conductive mesh layer is formed in a pattern having a tapered cross-section in which a pattern width is smaller on an upper side than on a lower side.

9. The photoelectric conversion element according to claim 1, wherein the translucent conductive mesh layer is formed in a pattern having a triangular cross-section in which a pattern width is smaller on an upper side than on a lower side.

10. The photoelectric conversion element according to claim 1, wherein the translucent conductive mesh layer is formed in a pattern having a trapezoidal cross-section in which a pattern width is smaller on an upper side than on a lower side.

11. The photoelectric conversion element according to claim 1, wherein the translucent conductive mesh layer is formed in a pattern having a half-moon cross-section in which a pattern width is smaller on an upper side than on a lower side.

12. The photoelectric conversion element according to claim 1, wherein the translucent conductive mesh layer is formed of an indium-oxide thin film containing a dopant element as a main component.

13. The photoelectric conversion element according to claim 12, wherein the translucent conductive base layer is formed of an indium-oxide thin film that contains less dopant element than the translucent conductive mesh layer and has a same composition as a composition of the translucent conductive mesh layer.

14. A manufacturing method of a photoelectric conversion element, the method comprising:
forming a photoelectric conversion layer; and
forming an electrode including a translucent conductive film on a first principal surface of the photoelectric conversion layer, wherein
the forming the electrode includes
forming a translucent conductive mesh layer formed in a translucent conductive film pattern on the photoelectric conversion layer, and
forming a translucent conductive base layer having higher electrical resistivity and higher translucency than electrical resistivity and translucency of the translucent conductive mesh layer such that the translucent conductive base layer covers the translucent conductive mesh layer.

15. The manufacturing method of a photoelectric conversion element according to claim 14, wherein
the forming the translucent conductive mesh layer includes
forming a first translucent conductive material made of an amorphous material on the photoelectric conversion layer,
forming a crystallized portion by selectively irradiating the first translucent conductive material with a laser beam, and
selectively removing a non-crystallized portion of the first translucent conductive material while leaving the crystallized portion.

16. The manufacturing method of a photoelectric conversion element according to claim 15, wherein the forming the translucent conductive base layer includes forming a second translucent conductive material having higher electrical resistivity and higher translucency than electrical resistivity and translucency of the first translucent conductive material.
